(19) United States
(12) Patent Application Publication
(10) Pub. No.: US 2020/0127662 A1
(43) Pub. Date: Apr. 23, 2020

(54) Inductive Touch Sensor and Method for Operating the Same

(71) Applicant: Deutsches Zentrum für Luft- und Raumfahrt e.V., Koeln (DE)

(72) Inventors: Maxime Chalon, Fuerstenfeldbruck (DE); Maximilian Maier, Fuerstenfeldbruck (DE)

(21) Appl. No.: 16/618,511

(22) PCT Filed: May 30, 2018
(86) PCT No.: PCT/EP2018/064294

§ 371 Date: Dec. 2, 2019

(30) Foreign Application Priority Data
May 31, 2017 (DE) 10 2017 209 250.5

(51) Int. Cl. H03K 17/975; H03K 17/95

(52) U.S. Cl. CPC H03K 17/975; H03K 2217/96038; H03K 17/952

(57) ABSTRACT

An inductive touch sensor including at least one magnetic field generating element for generating a magnetic field, at least one resonance element arranged in the magnetic field of the magnetic field generating element, a positioning element for positioning the at least one resonance element relative to the at least one magnetic field generating element, wherein the position of the resonance element relative to the at least one magnetic field generating element is adapted to be changed thereby changing the resonance generated in the resonance element by the magnetic field, an evaluation circuit for evaluating the change of the resonance of the resonance element such that thereby a detection of operation of the touch sensor is effected.

The invention relates to an inductive touch sensor as well as a method for operating the same.

In today's robotic applications or other applications in the industrial sector, frequently a haptic feedback is required, for example in an application for gripping an object or when operating machines. If, for example, it is intended to detect whether an object has been gripped, a capacitive sensor could be used which is also used in smartphone displays, for example. Furthermore, resistive sensors and inductive sensors are known. It is problematic that, on the one hand, only certain materials can be detected by sensors. Thus, a capacitive touch sensor cannot detect a piece of plastic material, for example. Resistive sensors have the drawback that they are strongly temperature-dependent.

It is an object of the invention to provide a touch sensor by means of which all materials can be detected and which enables a more accurate measurement.

Further, a method for operating such a sensor is to be provided.

According to the invention, the object is solved by the features of claims 1 and 8.

The inductive touch sensor according to the invention comprises at least one magnetic field generating element for generating a magnetic field. This may be a coil which is supplied with an alternating voltage via an excitation circuit such that a magnetic field is generated.

The inductive touch sensor according to the invention further comprises a resonance element which is arranged in the magnetic field of the magnetic field generating element. This may be a capacitor, for example. As an alternative to a capacitor, a coil can be used, for example, which is connected to a circuitry. The latter can include identification codes for each resonance element, for example. In all embodiments of the invention, it is preferred that the evaluation circuit can identify that resonance element whose resonance has been changed. As a resonance element, any element can be used which is excited to resonate by the magnetic field of the magnetic field generating element. Preferably, this takes place when the magnetic field generating element has been switched off, that is, when the latter is no longer supplied with voltage by the excitation circuit.

The inductive touch sensor further comprises a positioning element for positioning the at least one resonance element relative to the magnetic field generating element. This positioning element may be a resilient medium, for example silicone, inside which the resonance element is arranged. The position of the resonance element relative to the magnetic field generating element is thus adapted to be changed such that the resonance generated in the resonance element by the magnetic field is changed.

This change of the resonance of the resonance element is evaluated by an evaluation circuit such that thereby detection and operation of the inductive touch sensor is performed. In contrast to prior art sensors, the sensor according to the invention is not temperature-dependent and, further, is less susceptible to manufacturing inaccuracies. Further, this sensor can detect all materials.

It is preferred that on the side of the inductive touch sensor touched by the user, a screening element is arranged. Thereby an improvement of the measured signal can be achieved. The screening element preferably serves for screening integer multiples of the resonance frequency used.

Furthermore, it is preferred that, as an evaluation circuit, a separate measuring branch of the excitation circuit is used with the aid of which the magnetic field of the magnetic field generating element is generated. Alternatively, a separate circuit can be used as an evaluation circuit.

Furthermore, it is preferred that at least two magnetic field generating elements are provided which are excited at different frequencies. Thus, for example, the first magnetic field generating element can be excited at a higher frequency, while the second magnetic field generating element can be excited at a lower frequency. Further, in this embodiment, at least two resonance elements are used.

The invention further relates to a method for operating an inductive touch sensor, in particular one as described above. The method according to the invention can comprise all features of the device according to the invention, and vice versa.

In the method according to the invention, a magnetic field is generated by at least one magnetic field generating element. Subsequently, the magnetic field generating element is switched off by no longer supplying it with a voltage from the excitation circuit.

Now a changing resonance of at least one resonance element arranged in the magnetic field is measured. The resonance generated in the resonance element by the magnetic field changes since the position of the resonance element relative to the magnetic field generating element is adapted to be changed. According to the position of the resonance element relative to the magnetic field generating element, the resonance in the resonance element thus changes.

An evaluation circuit evaluates this change of the resonance of the resonance element such that thereby operation of the inductive touch sensor is detected.

According to a preferred embodiment, at least two magnetic field generating elements are excited at different frequencies. Furthermore, the resonance of at least two resonance elements arranged in the magnetic field is measured. The different resonating of the two resonance elements at the different frequencies indicates the position where the touch sensor has been touched. This embodiment of the method is based on the fact that the resonance elements merely respond to the specific frequency for which they have been designed. The resonance elements are thus excited at different frequencies (frequency multiplexing), whereupon their respective resonance is measured. Thereby it is possible to identify and localize the respective resonance element. For this purpose, a change of the amplitude of the electric signal of the respective resonance element is compared with a reference amplitude in the evaluation circuit, for example, such that information on a movement of the resonance element relative to the magnetic field generating element can be deduced.

Furthermore, it is preferred that, distributed over a touch sensor, a plurality of magnetic field generating elements are provided which can scan the overall surface of the touch sensor.

Furthermore, it is possible to generate, sequentially in time, magnetic fields with different frequencies by a single magnetic field generating element. Alternatively, it is also possible to use a plurality of magnetic field generating elements for generating the different frequencies. Inside this magnetic field, a plurality of resonance elements are arranged one upon the other, i.e. perpendicularly to the surface of the inductive touch sensor. For example, three resonance elements may be provided. Each of these resonance elements has a resonance frequency which responds to one of the different frequencies of the magnetic fields. For example, the uppermost resonance element may respond to the highest frequency, the middle resonance element may respond to the middle frequency, and the lower resonance element may respond to the lower frequency. If merely a low pressure is applied to the inductive touch sensor, only the uppermost resonance element may be displaced such that merely a response to the highest frequency of the magnetic field is detected but not a response to the magnetic fields with the middle and the low frequency. In this case, a touch at a low pressure can thus be assumed.

If, however, touching is effected at a higher pressure, the middle resonance element or even the lowermost resonance element responds to the middle and respectively the lower frequency of the magnetic field. In this manner, it is possible to detect the amount of pressure of the touch.

Preferably, it is possible to arrange the plurality of resonance elements, which are disposed one upon the other, in one material having a different hardness, notably a softer material for the surroundings of the first resonance element, a medium soft material for the surroundings of the second resonance element, and a harder material for the surroundings of the third resonance element. In this manner, the pressure of the touch can be detected even more exactly.

It is preferred that the electronic evaluation system is configured such that only the amplitude of the electric signal of the respective resonance element is observed, but not a frequency change. If magnetic fields of different frequencies are used, a plurality of parallel excitation generators and bandpass/envelope modules can be used between which a multiplexer can perform a changeover. Bandpass filtering is carried out to clean the signal and to extract the envelope. This can be effected by a rectifier (in the simplest form a simple diode). Alternatively, it is possible to us an active rectifier.

Hereunder preferred embodiments of the invention will be explained on the basis of the figures in which:

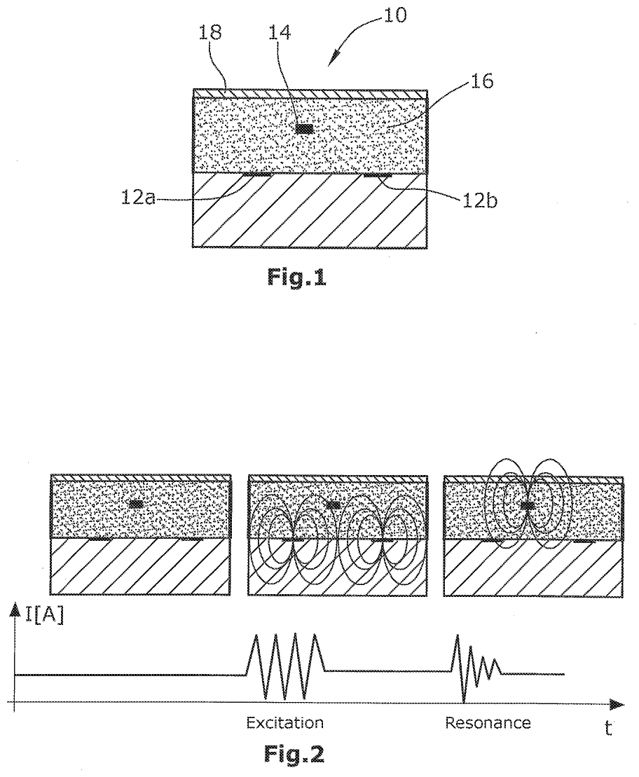

FIG. 1 shows a first embodiment of the touch sensor according to the invention,

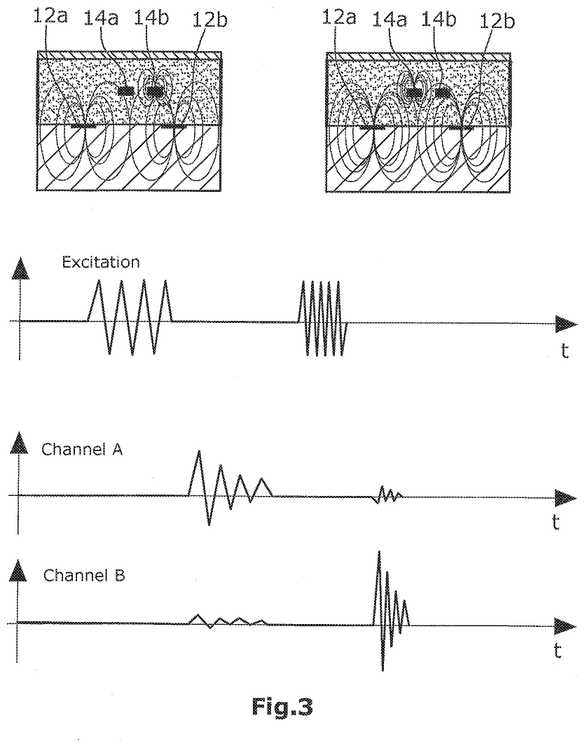

FIGS. 2 and 3 show various operating modes of the touch sensor according to the invention.

As illustrated in FIG. 1, the inductive touch sensor 10 comprises a first coil (12a) and a second coil (12b) which respectively generate a magnetic field.

The resonator (14) is arranged in this common magnetic field not illustrated in FIG. 1. It is located in the resilient material 16 which may comprise a silicone material, for example, and which serves as a positioning element by means of which the resonator 14 is positioned relative to the coils 12a, 12b.

The side of the sensor 10 facing the outside is provided with a screening element 18.

If an object touches this screening element 18, the resilient medium 16 is compressed such that the distance of the resonator 14 relative to the coils 12a and/or 12b becomes smaller. Thereby the resonance generated in the resonator 14 by the magnetic field of the coils 12a, 12b changes. This change of the resonance is detected and evaluated by an evaluation circuit not illustrated such that it is possible to detect whether, and preferably at which location, the inductive touch sensor has been touched by the object.

FIG. 2 illustrates how a measuring sequence may be performed. In the middle of FIG. 2, the excitation is illustrated which is caused by a pulse and supplied to the two coils 12a, 12b by an excitation circuit not illustrated. Thereafter, the coils are immediately switched off. Due to the excitation a magnetic field is generated. This, in turn, results in the resonator 14 also being induced to resonate. This is illustrated in the right part of FIG. 2. When the coils 12a, 12b are switched off, a measuring circuit can measure the strength of the resonance field of the resonance element 14.

Another embodiment of the device according to the invention and the method according to the invention is shown in FIG. 3. Here, two coils 12a, 12b are used which are each excited at a different frequency. Furthermore, at least two resonator elements 14a, 14b are used which are arranged in the common magnetic field of the two coils. As can be seen in the lower part of FIG. 3, the two resonator elements respond in a different manner to the different frequencies.

1. An inductive touch sensor comprising
at least one magnetic field generating element for generating a magnetic field,
at least one resonance element arranged in the magnetic field of the magnetic field generating element,
a positioning element for positioning the at least one resonance element relative to the at least one magnetic field generating element,
wherein the position of the resonance element relative to the at least one magnetic field generating element is adapted to be changed thereby changing the resonance generated in the resonance element by the magnetic field, and
an evaluation circuit for evaluating the change of the resonance of the resonance element such that thereby a detection of operation of the touch sensor is effected.

2. The inductive touch sensor according to claim 1, wherein the magnetic field generating element is a coil.

3. The inductive touch sensor according to claim 2, wherein the resonance element is a capacitor.

4. The inductive touch sensor according to claim 1, wherein the positioning element comprises a resilient medium inside which the resonance element is arranged.

5. The inductive touch sensor according to claim 1, wherein, on a side of the inductive touch sensor touched by a user, a screening element is arranged.

6. The inductive touch sensor according to claim 1, wherein as an evaluation circuit a separate measuring branch of an excitation circuit is used to generate the magnetic field of the magnetic field generating element.

7. The inductive touch sensor according to claim 1, wherein the inductive touch sensor comprises at least two magnetic field generating elements, the at least two magnetic field generating elements excited at different frequencies, and,
wherein the inductive touch sensor comprises at least two resonance elements.

8. A method for operating an inductive touch sensor according to claim 1, the method comprising:
generating a magnetic field using at least one magnetic field generating element,
measuring a changing resonance of at least one resonance element arranged in the magnetic field,
wherein a position of the resonance element relative to the at least one magnetic field generating element is adapted to be changed thereby changing the resonance generated in the resonance element by the magnetic field, and
evaluating the change of the resonance of the resonance element such that thereby a detection of operation of the inductive touch sensor is effected.

9. The method according to claim 8, further comprising:
exciting at least two magnetic field generating elements at different frequencies, and
measuring a resonance of at least two resonance elements arranged in the magnetic field,
wherein a different resonating of the two resonator elements at the different frequencies indicates a position where the inductive touch sensor has been touched.

10. The inductive touch sensor according to claim 4, wherein the resilient medium comprises silicone.
